(19) United States
(12) Patent Application Publication
(10) Pub. No.: US 2019/0371572 A1
(43) Pub. Date: Dec. 5, 2019

(54) FILM-FORMING METHOD AND FILM-FORMING APPARATUS

(71) Applicant: TOKYO ELECTRON LIMITED, Tokyo (JP)

(72) Inventors: Satoshi WAKABAYASHI, Nirasaki City (JP); Motoko NAKAGOMI, Nirasaki City (JP); Hideaki YAMASAKI, Nirasaki City (JP)

(21) Appl. No.: 16/429,890

(22) Filed: Jun. 3, 2019

(30) Foreign Application Priority Data
Jun. 5, 2018 (JP) 2018-108115

(51) Int. Cl. H01J 37/32; C23C 16/52; C23C 16/46; H01L 21/687; C23C 16/458

(52) U.S. Cl. CPC H01J 37/32449; C23C 16/52; C23C 16/46; H01J 37/32522; H01J 2237/3321; H01L 21/68742; H01J 37/32715; C23C 16/4586; H01J 37/32834

(57) ABSTRACT

A film-forming method includes: loading a substrate by raising a plurality of lift pins of a mounting table provided in a processing container to receive the substrate and lowering the plurality of lift pins to mount the substrate on an upper surface of the mounting table, the plurality of lift pins being configured to protrude from the upper surface of the mounting table and to support the substrate; preheating the substrate by heating the substrate mounted on the mounting table in a state where an inert gas has been introduced into the processing container; and forming a film on the substrate by introducing a processing gas into the processing container.

### CROSS-REFERENCE TO RELATED APPLICATION

This application is based upon and claims the benefit of priority from Japanese Patent Application No. 2018-108115, filed on Jun. 5, 2018, the entire contents of which are incorporated herein by reference.

### TECHNICAL FIELD

The present disclosure relates to a film-forming method and a film-forming apparatus.

### BACKGROUND

There is known a method in which a Ti film is formed on a substrate such as a semiconductor wafer or the like by mounting the substrate on a mounting table in a processing container and generating plasma in the processing container in a state in which a processing gas including a TiCl₄ gas and an H₂ gas is introduced into the processing container (for example, see Patent Document 1).

### RELATED ART DOCUMENT

### Patent Document

[Patent Document 1] JP 2015-124398

In the case of forming a film on a substrate by using plasma, when a defect such as a minute scratch or a particle is present on a back surface of the substrate, abnormal plasma discharge may occur between an upper surface of a mounting table and the back surface of the substrate, which may affect the characteristics of a device to be formed on the substrate.

### SUMMARY

Some embodiments of the present disclosure provide a technique capable of reducing defects which may be generated on a back surface of a substrate.

According to one embodiment of the present disclosure, there is provided a film-forming method, which includes: loading a substrate by raising a plurality of lift pins of a mounting table provided in a processing container to receive the substrate and lowering the plurality of lift pins to mount the substrate on an upper surface of the mounting table, the plurality of lift pins being configured to protrude from the upper surface of the mounting table and to support the substrate; preheating the substrate by heating the substrate mounted on the mounting table in a state in which an inert gas has been introduced into the processing container; and forming a film on the substrate by introducing a processing gas into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a plasma processing apparatus.

FIG. 2 is a flowchart showing an example of a film-forming method.

FIGS. 3A and 3B are diagrams showing a relationship between a time and a gas flow rate in a film-forming process.

FIG. 4 is a first diagram showing an example of a relationship between the kind of gas and the number of defects on a back surface of a wafer.

FIG. 5 is a second diagram showing an example of a relationship between the kind of gas and the number of defects on a back surface of a wafer.

FIG. 6 is a diagram showing an example of a relationship between a speed of lift pins and the number of defects on a back surface of a wafer.

FIG. 7 is a diagram showing an example of a relationship between film-forming conditions and the number of defects on a back surface of a wafer.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Non-limiting exemplary embodiments of the present disclosure will now be described with reference to the accompanying drawings. Throughout the accompanying drawings, the same or corresponding members or parts are denoted by the same or corresponding reference numerals, and redundant explanations thereof are omitted.

[Plasma Processing Apparatus]

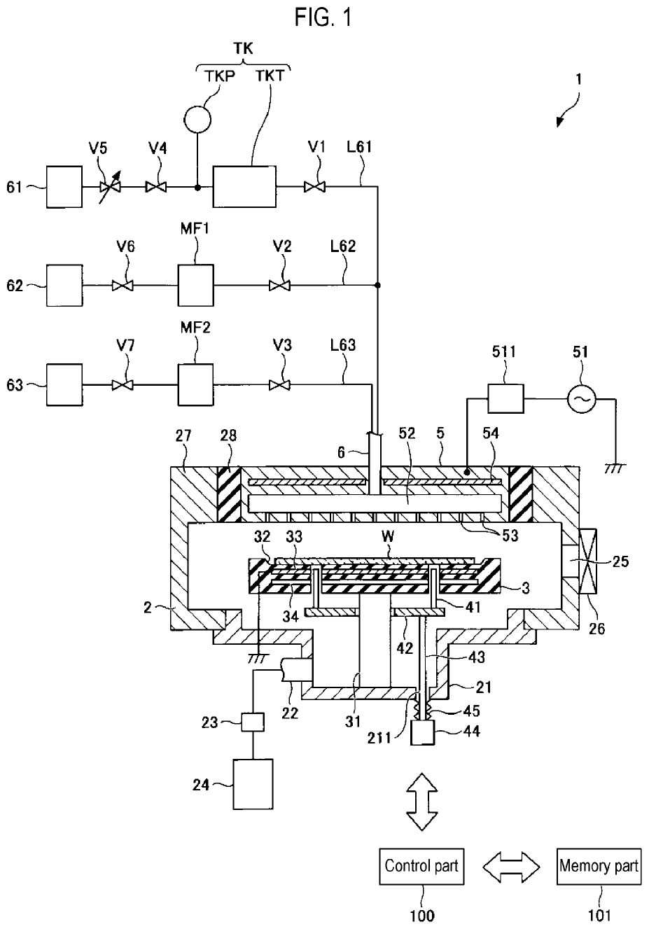

A film-forming apparatus for carrying out a film-forming method according to one embodiment of the disclosure will be described by taking a plasma processing apparatus as an example. FIG. 1 is a schematic sectional view showing an example of a plasma processing apparatus.

As shown in FIG. 1, the plasma processing apparatus 1 is an apparatus for forming a metal film, for example, a Ti (titanium) film or a TiN (titanium nitride) film, on a semiconductor wafer (hereinafter referred to as “wafer W”) as an example of a substrate by chemical vapor deposition (CVD) using plasma. The plasma processing apparatus 1 includes a substantially cylindrical airtight processing container 2. An exhaust chamber 21 is provided in a central portion of a bottom wall of the processing container 2.

The exhaust chamber 21 has, for example, a substantially cylindrical shape protruding downward. An exhaust path 22 is connected to the exhaust chamber 21, for example, on a side surface of the exhaust chamber 21.

An exhaust part 24 is connected to the exhaust path 22 via a pressure regulation part 23. The pressure regulation part 23 includes a pressure regulation valve such as, for example, a butterfly valve or the like. The exhaust path 22 is configured so that the interior of the processing container 2 can be depressurized by the exhaust part 24. On the side surface of the processing container 2, a transfer port 25 is provided. The transfer port 25 is configured to be freely opened and closed by a gate valve 26. The loading/unloading of the wafer W between the processing container 2 and a transfer chamber (not shown) is performed via the transfer port 25.

In the processing container 2, there is provided a stage 3 which is a mounting table for substantially horizontally holding the wafer W. The stage 3 is formed in a substantially circular shape in a plan view and is supported by a support member 31. On the surface of the stage 3, for example, a substantially circular recess 32 for mounting a wafer W having a diameter of 300 mm is formed. The recess 32 has an inner diameter slightly (for example, about 1 mm to 4 mm) larger than the diameter of the wafer W. For example, the depth of the recess 32 is set to be substantially the same as the thickness of the wafer W. The stage 3 is made of a ceramic material such as, for example, aluminum nitride (AlN) or the like. Furthermore, the stage 3 may be made of a metal material such as nickel (Ni) or the like. Instead of the recess 32, a guide ring for guiding the wafer W may be provided in the peripheral edge portion of the surface of the stage 3.

For example, a grounded lower electrode 33 is buried in the stage 3. A heating mechanism 34 is buried under the lower electrode 33. The heating mechanism 34 is supplied with electric power from a power supply part (not shown) based on a control signal from control part 100, thereby heating the wafer W mounted on the stage 3 to a set temperature (for example, a temperature of 300 to 700 degrees C.). In the case where the entire stage 3 is made of metal, the entire stage 3 functions as a lower electrode. Therefore, the lower electrode 33 need not be buried in the stage 3. A plurality of (for example, three) lift pins 41 for holding and lifting the wafer W mounted on the stage 3 is provided in the stage 3. The material of the lift pins 41 may be, for example, ceramics such as alumina (Al₂O₃) or the like, or quartz. The lower ends of the lift pins 41 are attached to a support plate 42. The support plate 42 is connected to an elevating mechanism 44 provided outside the processing container 2 via an elevating shaft 43.

The elevating mechanism 44 is installed, for example, under the exhaust chamber 21. A bellows 45 is provided between an opening 211 for the elevating shaft 43 formed on the lower surface of the exhaust chamber 21 and the elevating mechanism 44. The shape of the support plate 42 may be any shape as long as the support plate 42 may move up and down without interfering with the support member 31 of the stage 3. The lift pins 41 are configured to be vertically movable between the upper side of the surface of the stage 3 and the lower side of the surface of the stage 3 by the elevating mechanism 44. In other words, the lift pins 41 are configured to be able to protrude from the upper surface of the stage 3.

A gas supply part 5 is provided in a top wall 27 of the processing container 2 via an insulating member 28. The gas supply part 5 forms an upper electrode and faces the lower electrode 33. A high frequency power supply 51 is connected to the gas supply part 5 via a matcher 511. By supplying high frequency power from the high frequency power supply 51 to the upper electrode (gas supply part 5), a high frequency electric field is generated between the upper electrode (gas supply part 5) and the lower electrode 33. The gas supply part 5 includes a hollow gas supply chamber 52. On the lower surface of the gas supply chamber 52, for example, a large number of holes 53 for distributing and supplying a processing gas into the processing container 2 are arranged at equal intervals. The heating mechanism 54 is buried, for example, above the gas supply chamber 52 in the gas supply part 5. The heating mechanism 54 is heated to a set temperature by being supplied with electric power from a power supply part (not shown) based on a control signal from the control part 100.

In the gas supply chamber 52, a gas supply path 6 is provided. The gas supply path 6 communicates with the gas supply chamber 52. A gas source 61 is connected to the upstream side of the gas supply path 6 via a gas line L61, a gas source 62 is connected to the upstream side of the gas supply path 6 via a gas line L62, and a gas source 63 is connected to the upstream side of the gas supply path 6 via a gas line L63. In one embodiment, the gas source 61 is a gas source of an inert gas and may be a gas source of, for example, an argon (Ar) gas, a nitrogen (N₂) gas or the like. The gas source 62 is a gas source of a processing gas and may be a gas source of, for example, a hydrogen (H₂) gas, an ammonia (NH₃) gas or the like. The gas source 62 may be used as a gas source of a purging-purpose inert gas (an Ar gas, an N₂ gas or the like). The gas source 63 is a gas source of a processing gas and may be a gas source of, for example, a titanium chloride (TiCl₄) gas or the like. The gas source 63 may be used as a gas source of a purging-purpose inert gas (an Ar gas, an N₂ gas or the like). The gas line L61 and the gas line L62 are connected to each other between a valve V1 in the gas line L61 and the gas supply path 6 and between a valve V2 in the gas line L62 and the gas supply path 6.

The gas source 61 is connected to the gas supply path 6 via the gas line L61. In the gas line L61, a pressure regulation valve V5, a valve V4, a pressure increasing part TK and a valve V1 are provided in this order from the side of the gas source 61. The pressure increasing part TK is disposed between the valve V1 and the valve V4 in the gas line L61. The valve V4 is disposed between the pressure regulation valve V5 and the pressure increasing part TK. The pressure increasing part TK includes a gas storage tank TKT. The gas storage tank TKT of the pressure increasing part TK may store the gas supplied from the gas source 61 via the gas line L61 and the valve V4 in a state in which the valve V1 is closed and the valve V4 is opened, and may increase the pressure of the gas in the gas storage tank TKT. The pressure increasing part TK includes a pressure gauge TKP. The pressure gauge TKP measures the pressure of the gas inside the gas storage tank TKT of the pressure increasing part TK and transmits a measurement result to the control part 100. The valve V1 is disposed between the pressure increasing part TK and the gas supply path 6.

The gas source 62 is connected to the gas supply path 6 via the gas line L62. In the gas line L62, a valve V6, a mass flow controller MF1 and a valve V2 are provided in this order from the side of the gas source 62.

The gas source 63 is connected to the gas supply path 6 via the gas line L63. In the gas line L63, a valve V7, a mass flow controller MF2 and a valve V3 are provided in this order from the side of the gas source 63.

The plasma processing apparatus 1 includes a control part 100 and a memory part 101. The control part 100 includes a CPU, a RAM, a ROM and the like, which are not shown, and comprehensively controls the plasma processing apparatus 1 by, for example, causing the CPU to execute a computer program stored in the ROM or the memory part 101. Specifically, the control part 100 causes the CPU to execute the control program stored in the memory part 101 to control the operation of each component of the plasma processing apparatus 1, thereby executing plasma processing or the like on the wafer W.

[Film-Forming Method]

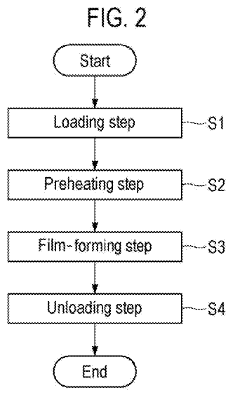

A film-forming method according to one embodiment of the present disclosure will be described by taking as an example a case of forming a Ti film using the plasma processing apparatus 1 shown in FIG. 1. FIG. 2 is a flowchart showing an example of a film-forming method.

As shown in FIG. 2, the film-forming method according to one embodiment of the present disclosure is a method of performing a loading step S1, a preheating step S2, a film-forming step S3 and an unloading step S4 in the named order.

In the loading step S1, the gate valve 26 is first opened, and the wafer W is loaded into the processing container 2 from the transfer chamber (not shown) via the transfer port 25 by a transfer arm (not shown). Subsequently, the lift pins 41 are raised (moved) from the lower side to the upper side of the surface of the stage 3 by the elevating mechanism 44 so that the lift pins 41 protrude from the recess 32 of the stage 3, and the wafer W is mounted on the lift pins 41. Then, after the transfer arm is retracted to the transfer chamber, the lift pins 41 are lowered (moved) to the lower side of the surface of the stage 3 by the elevating mechanism 44. As a result, the distal ends of the lift pins 41 are accommodated in the stage 3, and the wafer W is mounted on the recess 32 of the stage 3. In the loading step S1, it is preferable to lower the lift pins 41 at a speed of 1 to 15 mm/sec. More preferably, the speed is 3 to 10 mm/sec. As a result, it is possible to suppress rubbing between the distal ends of the lift pins 41 and the back surface of the wafer W when the lift pins 41 are lowered while holding the wafer W and generation of rubbing due to the vibration of the lift pins 41 when the wafer W is mounted on the upper surface of the recess 32 of the stage 3. Furthermore, in the loading step S1, it is preferable to raise the lift pins 41 at a speed of 1 to 15 mm/sec. More preferably, the speed is 3 to 10 mm/sec. This makes it possible to suppress rubbing between the distal ends of the lift pins 41 and the back surface of the wafer W due to the push-up of the lift pins 41 when the wafer W is delivered between the transfer arm and the lift pins 41.

In the preheating step S2, the gate valve 26 is closed, and the temperature of the stage 3 is controlled by the heating mechanism 34 to control the temperature of the wafer W. While the interior of the processing container 2 is evacuated by the exhaust part 24, the pressure inside the processing container 2 is regulated to a predetermined pressure (for example, 100 to 1500 Pa) by the pressure regulation part 23. Furthermore, an inert gas such as an Ar gas, an N₂ gas or the like is introduced into the processing container 2 from the gas source 61 via the gas line L61, the gas supply path 6 and the gas supply chamber 52. In the preheating step S2, the wafer W is heated to a temperature of, for example, 300 to 700 degrees C. In the preheating step S2, from the viewpoint of preventing deformation of the wafer W when heating the wafer W, it is preferred that the supply amount of the inert gas is gradually increased to the set flow rate (hereinafter referred to as “flow rate ramp-up”) at the initial stage of heating. The method of controlling the flow rate ramp-up of the inert gas may be a method of continuously increasing the flow rate with respect to the time or a method of increasing the flow rate stepwise with respect to the time. The time from the start of increase of the supply amount of the inert gas to the arrival at a set flow rate (hereinafter referred to as “flow rate ramp-up time”) may be, for example, 1 to 30 sec, more preferably 3 to 7 sec. In the preheating step S2, it is preferred that the lift pins 41 are raised to the upper side of the surface of the stage 3 by the elevating mechanism 44 at the initial stage of heating so as to provide a gap between the upper surface of the recess 32 of the stage 3 and the back surface of the wafer W. This makes it possible to prevent the wafer W from being deformed due to occurrence of a sudden temperature difference between the front surface and the back surface of the wafer W when heating the wafer W. The gap between the upper surface of the recess 32 of the stage 3 and the back surface of the wafer W may be small, preferably about 0.5 to 3.0 mm.

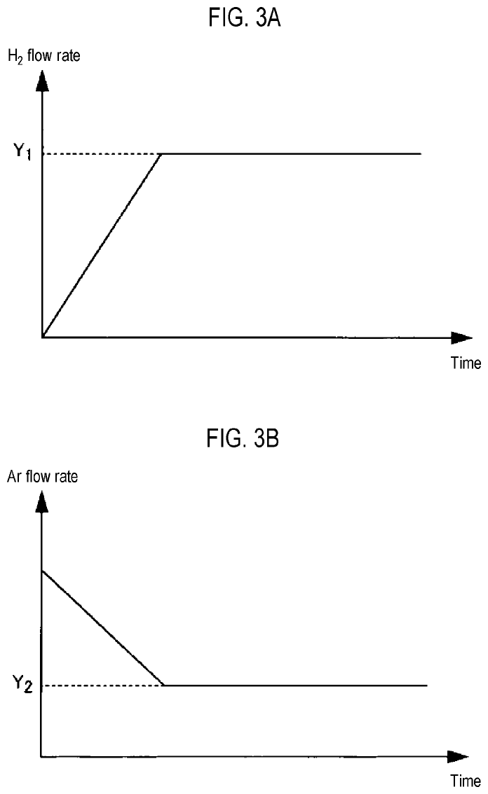

In the film-forming S3, the temperature of the stage 3 is controlled by the heating mechanism 34 to control the temperature of the wafer W. Furthermore, while evacuating the interior of the processing container 2 by the exhaust part 24, the pressure inside the processing container 2 is regulated to a predetermined pressure (for example, 100 to 1500 Pa) by the pressure regulation part 23. Moreover, a TiCl₄ gas is introduced into the processing container 2 from the gas source 63 via the gas line L63, the gas supply path 6 and the gas supply chamber 52. Furthermore, an H₂ gas is introduced into the processing container 2 from the gas source 62 via the gas line L62, the gas supply path 6 and the gas supply chamber 52. Moreover, an Ar gas is introduced into the processing container 2 from the gas source 61 via the gas line L61. In addition, the high frequency power is supplied from the high frequency power supply 51 to the upper electrode (gas supply part 5) via the matcher 511 in a state in which the processing gas has been introduced into the processing container 2, whereby a high frequency electric field is generated between the upper electrode (gas supply part 5) and the lower electrode 33. Plasma of the processing gas is generated by the high frequency electric field generated between the upper electrode and the lower electrode 33. A Ti film is formed on the wafer W by the plasma of the processing gas. FIGS. 3A and 3B are diagrams showing the relationship between the time and the gas flow rate in the film-forming step S3. FIG. 3A shows the relationship between the time and the flow rate of the H₂ gas, and FIG. 3B shows the relationship between the time and the flow rate of the Ar gas. In FIG. 3A, the time is indicated on the horizontal axis, the flow rate of the H₂ gas is indicated on the vertical axis, and the set flow rate of the H₂ gas is indicated by Y1. In FIG. 3B, the time is indicated on the horizontal axis, the flow rate of the Ar gas is indicated on the vertical axis, and the set flow rate of the Ar gas is indicated by Y2. The film-forming step S3 preferably includes a step of, at the beginning of film formation, gradually increasing the supply amount of the H₂ gas to the set flow rate Y1 as shown in FIG. 3A and gradually decreasing the supply amount of the Ar gas to the set flow rate Y2 as shown in FIG. 3B. By using the ramp-up and the ramp-down in this manner, the change in heat transfer to the wafer W becomes gentle, which makes it possible to prevent warpage of the wafer W. At the initial stage of film formation in film-forming step S3, the TiCl₄ gas may be supplied or may not be supplied. Furthermore, in the film-forming step S3, from the viewpoint of reducing dust and scratches generated on the back surface of the wafer W, it is preferable that the flow rate of the H₂ gas is higher than the flow rate of the Ar gas. For example, the H₂/Ar flow rate ratio which is a ratio of the flow rate of the H₂ gas to the flow rate of Ar gas is preferably 2 to 10, more preferably 3 to 8.

In the unloading step S4, first, the lift pins 41 are raised from the lower side to the upper side of the surface of the stage 3 by the elevating mechanism 44 so that the lift pins 41 protrude from the recess 32 of the stage 3, whereby the wafer W is lifted up by the lift pins 41. Then, the gate valve 26 is opened, the transfer arm is inserted under the wafer W placed on the lift pins 41, and the lift pins 41 are lowered from the upper side to the lower side of the stage 3. As a result, the distal ends of the lift pins 41 are accommodated in the stage 3, and the wafer W is placed on the transfer arm. Subsequently, the wafer W is unloaded from the processing container 2 to the transfer chamber via the transfer port 25 by the transfer arm. In the unloading step S4, it is preferable to raise the lift pins 41 at a speed of 1 to 15 mm/sec. More preferably, the speed is 3 to 10 mm/sec. As a result, it is possible to suppress the rubbing between the distal ends of the lift pins 41 and the back surface of the wafer W when the lift pins 41 are moved up while holding the wafer W and to suppress an increase in back surface scratch due to a shift of the wafer W when the wafer W is lifted up from the upper surface of the recess 32 of the stage 3 by the lift pins 41.

When film formation is carried out using the plasma processing apparatus 1 as described above, minute defects such as scratches or particles may be generated on the back surface of the wafer W due to the push-up of the lift pins 41 when delivering the wafer W between the transfer arm and the lift pins 41. Furthermore, rubbing may occur between the distal ends of the lift pins 41 and the back surface of the wafer W when raising and lowering the lift pins 41 while holding the wafer W, or defects such as minute scratches or particles may be generated on the back surface of the wafer W due to the friction when the wafer W makes contact with the upper surface of the recess 32 of the stage 3. Moreover, minute defects such as scratches or particles may be generated on the back surface of the wafer W due to deformation such as warpage of the wafer W caused by the rapid heating of the wafer W mounted in the recess 32 of the stage 3. If defects are generated on the back surface of the wafer W as described above, abnormal plasma discharge (for example, micro-arcing) may occur between the upper surface of the stage 3 and the back surface of the wafer W. The occurrence of the abnormal plasma discharge may affect the characteristics of a device formed on the wafer W.

In the film-forming method according to one embodiment of the present disclosure, after the wafer W is mounted in the recess 32 of the stage 3, the wafer W is heated in a state in which the inert gas such as an Ar gas, an N₂ gas or the like has been introduced into the processing container 2. Since the inert gas such as an Ar gas, an N₂ gas or the like is a gas having a lower thermal conductivity than the conventionally used H₂ gas, the wafer W loaded into the processing container 2 and just mounted in the recess 32 of the stage 3 is gradually heated. Therefore, it is possible to suppress deformation such as warpage of the wafer W, whereby the degree of rubbing between the back surface of the wafer W and the upper surface of the stage 3 becomes small. As a result, it is possible to reduce defects such as minute scratches or particles generated on the back surface of the wafer W and to suppress occurrence of abnormal plasma discharge due to such defects. The timing of introducing the gas such as the Ar gas or the N₂ gas is preferably after the wafer W is mounted in the recess 32 of the stage 3. However, in order to suppress the abrupt temperature change of the wafer W, the gas such as the Ar gas or the N₂ gas may be introduced before the wafer W is mounted in the recess 32 of the stage 3.

Furthermore, in the film-forming method according to one embodiment of the present disclosure, the lift pins 41 are lowered at a speed of 1 to 15 mm/sec in the loading step S1. As a result, it is possible to particularly suppress the occurrence of rubbing between the distal ends of the lift pins 41 and the back surface of the wafer W when the lift pins 41 is moved down while holding the wafer W or the occurrence of rubbing due to the vibration of the lift pins 41 when the wafer W is mounted on the upper surface of the recess 32 of the stage 3. Furthermore, in the loading step S1, the lift pins 41 are raised at a speed of 1 to 15 mm/sec. This makes it possible to particularly suppress the rubbing between the distal ends of the lift pins 41 and the back surface of the wafer W due to the push-up of the lift pins 41 when delivering the wafer W between the transfer arm and the lift pins 41.

In addition, in the film-forming method according to one embodiment of the present disclosure, the lift pins 41 are raised at a speed of 1 to 15 mm/sec in the unloading step S4. As a result, it is possible to particularly suppress the rubbing between the distal ends of the lift pins 41 and the back surface of the wafer W when the lift pins 41 are moved up while holding the wafer W and to suppress an increase in the back surface scratch due to the shift of the wafer W when the wafer W is lifted up from the upper surface of the recess 32 of the stage 3 by the lift pins 41.

### EXAMPLES

### Example 1

In Example 1, a comparison was conducted on the number of defects generated on the back surface of the wafer W when the kind of gas to be introduced into the processing container 2 is changed at the time of preheating the wafer W.

First, using the plasma processing apparatus 1 shown in FIG. 1, the wafer W was mounted in the recess 32 of the stage 3, the wafer W was heated in a state in which an Ar gas has been introduced into the processing container 2, and then the number of defects present on the back surface of the wafer W was measured. Specific process conditions are as follows, and steps S11A to S12A were carried out in the named order.

<Process Conditions>

Step S11A
Time: 2 sec
Gap between stage upper surface and wafer back surface: 1 mm
Gas flow rate: Ar (1440 sccm)
Ar flow rate ramp-up time: 2 sec
Pressure inside processing container: a vacuum state is maintained

Step S12A
Time: 13 sec
Gap between stage upper surface and wafer back surface: 0 mm
Gas flow rate: Ar (3600 sccm)
Ar flow rate ramp-up time: 3 sec
Pressure inside processing container: 1200 Pa

Furthermore, using the plasma processing apparatus 1 shown in FIG. 1, the wafer W was mounted in the recess 32 of the stage 3, the wafer W was heated in a state in which an N₂ gas has been introduced into the processing container 2, and then the number of defects present on the back surface of the wafer W was measured. Specific process conditions are as follows, and steps S11B to S12B were carried out in the named order.

<Process Conditions>

Step S11B
Time: 2 sec
Gap between stage upper surface and wafer back surface: 1 mm
Gas flow rate: N₂ (1440 sccm)
N₂ flow rate ramp-up time: 2 sec
Pressure inside processing container: a vacuum state is maintained

Step S12B
Time: 13 sec
Gap between stage upper surface and wafer back surface: 0 mm
Gas flow rate: N₂ (3600 sccm)
N₂ flow rate ramp-up time: 3 sec
Pressure inside processing container: 1200 Pa

In addition, using the plasma processing apparatus 1 shown in FIG. 1, the wafer W was mounted in the recess 32 of the stage 3, the wafer W was heated in a state in which an H₂ gas has been introduced into the processing container 2, and then the number of defects present on the back surface of the wafer W was measured. Specific process conditions are as follows, and steps S11C to S12C were carried out in the named order.

<Process Conditions>

Step S11C
Time: 2 sec
Gap between stage upper surface and wafer back surface: 1 mm
Gas flow rate: H₂ (1600 sccm)
H₂ flow rate ramp-up time: 2 sec
Pressure inside processing container: a vacuum state is maintained

Step S12C
Time: 13 sec
Gap between stage upper surface and wafer back surface: 0 mm
Gas flow rate: H₂ (4000 sccm)
H₂ flow rate ramp-up time: 3 sec
Pressure inside processing container: 1200 Pa

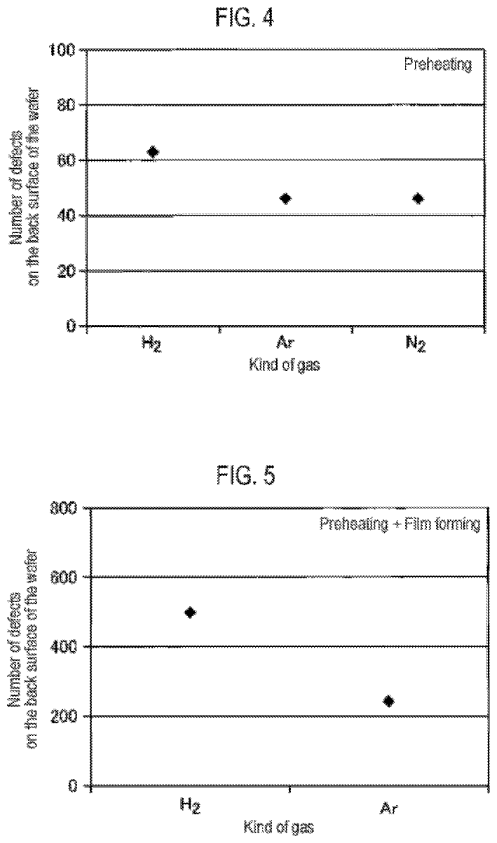

FIG. 4 is a diagram showing an example of the relationship between the kind of gas and the number of defects on the back surface of the wafer. FIG. 4 shows the number of defects on the back surface of the wafer W for each kind of gas.

As shown in FIG. 4, when the wafer W was heated in a state in which the H₂ gas has been introduced into the processing container 2, it was confirmed that 63 defects were generated on the back surface of the wafer W. On the other hand, when the wafer W was heated in a state in which the Ar gas or the N₂ gas has been introduced into the processing container 2, it was confirmed that 46 defects were generated on the back surface of the wafer W.

From these results, it may be said that, in the preheating step S2, the heating of the wafer W in a state in which the Ar gas or the N₂ gas has been introduced is effective for reducing the defects generated on the back surface of the wafer W.

### Example 2

In Example 2, a comparison was conducted on the number of defects generated on the back surface of the wafer W when the type of gas to be introduced into the processing container 2 at the time of preheating the wafer W is changed and a Ti film is formed on the wafer W.

First, using the plasma processing apparatus 1 shown in FIG. 1, the wafer W was mounted in the recess 32 of the stage 3, the wafer W was heated in a state in which an Ar gas has been introduced into the processing container 2, and then the plasma of a TiCl₄ gas and an H₂ gas was generated to form a Ti film on the wafer W. Moreover, the number of defects present on the back surface of the wafer W was measured. Specific process conditions are as follows, and steps S21A to S24A were carried out in the named order. Steps S21A to S22A are preheating steps, and steps S23A to S24A are film-forming steps.

<Process Conditions>

Step S21A
Time: 2 sec
Gap between stage upper surface and wafer back surface: 1 mm
Gas flow rate: Ar (1440 sccm)
Ar flow rate ramp-up time: 2 sec
Pressure inside processing container: a vacuum state is maintained

Step S22A
Time: 13 sec
Gap between stage upper surface and wafer back surface: 0 mm
Gas flow rate: Ar (3600 sccm)
Ar flow rate ramp-up time: 3 sec
Pressure inside processing container: 1200 Pa

Step S23A
Time: 6 sec
Gap between stage upper surface and wafer back surface: 0 mm
Gas flow rate: Ar (100 to 3000 sccm), H₂ (125 to 6250 sccm)
Ar flow rate ramp-down time: 3 sec
H₂ flow rate ramp-up time: 3 sec
Pressure inside processing container: 100 to 800 Pa

Step S24A
Time: 8 sec
Gap between stage upper surface and wafer back surface: 0 mm
Gas flow rate: TiCl₄ (1.0 to 30.0 sccm), Ar (100 to 3000 sccm), H₂ (125 to 6250 sccm)
Pressure inside processing container: 100 to 800 Pa

Further, using the plasma processing apparatus 1 shown in FIG. 1, the wafer W was mounted in the recess 32 of the stage 3, the wafer W was heated in a state in which an H₂ gas has been introduced into the processing container 2, and then the plasma of a TiCl₄ gas and an H₂ gas was generated to form a Ti film on the wafer W. Moreover, the number of defects present on the back surface of the wafer W was measured. Specific process conditions are as follows, and steps S21B to S24B were carried out in the named order. Steps S21B to S22B are preheating steps, and steps S23B to S24B are film-forming steps.

<Process Conditions>

Step S21B
Time: 2 sec
Gap between stage upper surface and wafer back surface: 1 mm
Gas flow rate: H₂ (1600 sccm)
H₂ flow rate ramp-up time: 2 sec
Pressure inside processing container: a vacuum state is maintained

Step S22B
Time: 13 sec
Gap between stage upper surface and wafer back surface: 0 mm
Gas flow rate: H₂ (4000 sccm)
H₂ flow rate ramp-up time: 3 sec
Pressure inside processing container: 1200 Pa

Step S23B
Time: 6 sec
Gap between stage upper surface and wafer back surface: 0 mm
Gas flow rate: Ar (100 to 3000 sccm), H₂ (125 to 6250 sccm)
Ar flow rate ramp-down time: 3 sec
H₂ flow rate ramp-up time: 3 sec
Pressure inside processing container: 100 to 800 Pa

Step S24B
Time: 8 sec
Gap between stage upper surface and wafer back surface: 0 mm
Gas flow rate: TiCl₄ (1.0 to 30.0 sccm), Ar (100 to 3000 sccm), H₂ (125 to 6250 sccm)
Pressure inside processing container: 100 to 800 Pa

FIG. 5 is a diagram showing an example of the relationship between the kind of gas and the number of defects on the back surface of the wafer. FIG. 5 shows the number of defects on the back surface of the wafer W for each kind of gas.

As shown in FIG. 5, when the wafer W was heated in a state in which the H₂ gas has been introduced into the processing container 2, it was confirmed that 498 defects were generated on the back surface of the wafer W. On the other hand, when the wafer W was heated in a state in which the Ar gas has been introduced into the processing container 2, it was confirmed that 243 defects were generated on the back surface of the wafer W.

From these results, it can be said that, in the preheating step S2, the heating of the wafer W in a state in which the Ar gas has been introduced is effective for reducing the defects generated on the back surface of the wafer W.

### Example 3

In Example 3, a comparison was conducted on the number of defects generated on the back surface of the wafer W when the moving speed of the lift pins 41 at the time of loading the wafer W into the processing container 2 is changed.

First, using the plasma processing apparatus 1 shown in FIG. 1, the wafer W was mounted in the recess 32 of the stage 3 while changing the raising and lowering speed of the lift pins 41 between 3 and 20 mm/sec, and then the wafer W was heated in a state in which an Ar gas has been introduced into the processing container 2. Further, the number of defects present on the back surface of the wafer W was measured. Specific process conditions are as follows, and steps S31A to S32A were carried out in the named order.

<Process Conditions>

Step S31A
Time: 2 sec
Gap between stage upper surface and wafer back surface: 1 mm
Gas flow rate: Ar (1440 sccm)
Ar flow rate ramp-up time: 2 sec
Pressure inside processing container: a vacuum state is maintained

Step S32A
Time: 13 sec
Gap between stage upper surface and wafer back surface: 0 mm
Gas flow rate: Ar (3600 sccm)
Ar flow rate ramp-up time: 3 sec
Pressure inside processing container: 1200 Pa

Further, using the plasma processing apparatus 1 shown in FIG. 1, the wafer W was mounted in the recess 32 of the stage 3 while changing the raising and lowering speed of the lift pins 41 between 3 and 20 mm/sec, and then the wafer W was heated in a state in which an H₂ gas has been introduced into the processing container 2. Further, the number of defects present on the back surface of the wafer W was measured. Specific process conditions are as follows, and steps S31B to S32B were carried out in the named order.

<Process Conditions>

Step S31B
Time: 2 sec
Gap between stage upper surface and wafer back surface: 1 mm
Gas flow rate: H₂ (1600 sccm)
H₂ flow rate ramp-up time: 2 sec
Pressure inside processing container: a vacuum state is maintained

Step S32B
Time: 13 sec
Gap between stage upper surface and wafer back surface: 0 mm
Gas flow rate: H₂ (4000 sccm)
H₂ flow rate ramp-up time: 3 sec
Pressure inside processing container: 1200 Pa

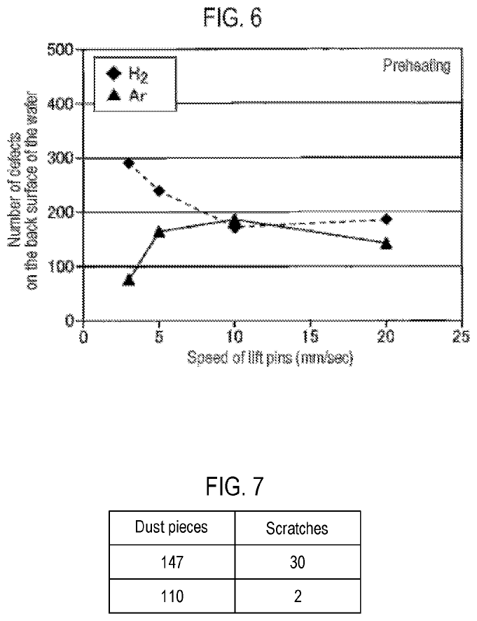

FIG. 6 is a diagram showing an example of the relationship between the speed of the lift pins and the number of defects on the back surface of the wafer. In FIG. 6, the speed (mm/sec) of the lift pins is indicated on the horizontal axis, and the number of defects on the back surface of the wafer is indicated on the vertical axis. Further, in FIG. 6, the result obtained when the preheating is performed using the H₂ gas is indicated by rhombic marks, and the result obtained when the preheating is performed using the Ar gas is indicated by triangular marks.

As shown in FIG. 6, when the speed of the lift pins 41 is set to 3 mm/sec, 5 mm/sec, 10 mm/sec and 20 mm/sec in the case of using the H₂ gas, it was confirmed that 290 defects, 239 defects, 172 defects and 185 defects were respectively generated on the back surface of the wafer W. That is, in the case of using the H₂ gas, when the speed of the lift pins 41 is lowered, the number of defects generated on the back surface of the wafer W increases. When the speed of the lift pins 41 is set to a low speed of 3 mm/sec, it was confirmed that the number of defects generated on the back surface of the wafer W reaches about 300 pieces.

In contrast, when the speed of the lift pins 41 is set to 3 mm/sec, 5 mm/sec, 10 mm/sec and 20 mm/sec in the case of using the Ar gas, it was confirmed that 76 defects, 164 defects, 186 defects and 142 defects were respectively generated on the back surface of the wafer W. That is, it was confirmed that, by setting the speed of the lift pins 41 to a low speed (for example, 3 mm/sec or less) in the case of using the Ar gas, it is possible to greatly reduce the defects generated on the back surface of the wafer W.

### Example 4

In Example 4, a comparison was conducted on the number of defects generated on the back surface of the wafer W when changing an H₂/Ar flow rate ratio, which is a ratio of an H₂ gas flow rate to an Ar gas flow rate in the case of forming a Ti film on the wafer W.

First, using the plasma processing apparatus 1 shown in FIG. 1, a Ti film was formed on the wafer W while controlling the H₂/Ar flow rate ratio to 5 at the time of forming the Ti film on the wafer W, and then the number of defects present on the back surface of the wafer W was measured. Specific process conditions are as follows, and steps S41A to S44A were carried out in the named order. Steps S41A to S42A are preheating steps, and steps S43A to S44A are film-forming steps.

<Process Conditions>

Step S41A
Time: 2 sec
Gap between stage upper surface and wafer back surface: 1 mm
Gas flow rate: Ar (1440 sccm)
Ar flow rate ramp-up time: 2 sec
Pressure inside processing container: a vacuum state is maintained

Step S42A
Time: 13 sec
Gap between stage upper surface and wafer back surface: 0 mm
Gas flow rate: Ar (3600 sccm)
Ar flow rate ramp-up time: 3 sec
Pressure inside processing container: 1200 Pa

Step S43A
Time: 6 sec
Gap between stage upper surface and wafer back surface: 0 mm
Gas flow rate: Ar (100 to 2000 sccm), H₂ (500 to 10000 sccm)
Ar flow rate ramp-down time: 3 sec
H₂ flow rate ramp-up time: 3 sec
Pressure inside processing container: 100 to 800 Pa

Step S44A
Time: 8 sec
Gap between stage upper surface and wafer back surface: 0 mm
Gas flow rate: TiCl₄ (1.0 to 30.0 sccm), Ar (100 to 2000 sccm), H₂ (500 to 10000 sccm)
Pressure inside processing container: 100 to 800 Pa

Further, using the plasma processing apparatus 1 shown in FIG. 1, a Ti film was formed on the wafer W while controlling the H₂/Ar flow rate ratio to 1.25 at the time of forming the Ti film on the wafer W, and then the number of defects present on the back surface of the wafer W was measured. Specific process conditions are as follows, and steps S41B to S44B were carried out in the named order. Steps S41B to S42B are preheating steps, and steps S43B to S44B are film-forming steps.

<Process Conditions>

Step S41B
Time: 2 sec
Gap between stage upper surface and wafer back surface: 1 mm
Gas flow rate: Ar (1440 sccm)
Ar flow rate ramp-up time: 2 sec
Pressure inside processing container: a vacuum state is maintained

Step S42B
Time: 13 sec
Gap between stage upper surface and wafer back surface: 0 mm
Gas flow rate: Ar (3600 sccm)
Ar flow rate ramp-up time: 3 sec
Pressure inside processing container: 1200 Pa

Step S43B
Time: 6 sec
Gap between stage upper surface and wafer back surface: 0 mm
Gas flow rate: Ar (100 to 2000 sccm), H₂ (125 to 2500 sccm)
Ar flow rate ramp-down time: 3 sec
H₂ flow rate ramp-up time: 3 sec
Pressure inside processing container: 100 to 800 Pa

Step S44B
Time: 8 sec
Gap between stage upper surface and wafer back surface: 0 mm
Gas flow rate: Ar (100 to 2000 sccm), H₂ (125 to 2500 sccm)
Pressure inside processing container: 100 to 800 Pa

FIG. 7 is a diagram showing an example of the relationship between the film-forming conditions and the number of defects on the back surface of the wafer. The upper part of FIG. 7 shows the results obtained when steps S41B to S44B were performed, and the lower part of FIG. 7 shows the results obtained when steps S41A to S44A were performed. Further, in the upper and lower parts of FIG. 7, the number of dust pieces among the defects generated on the back surface of the wafer W is shown in the left diagram, and the number of scratches among the defects is shown in the right diagram.

As shown in the upper part of FIG. 7, when the H₂/Ar flow rate ratio at the time of forming the Ti film on the wafer W is set to 1.25, it was confirmed that 147 dust pieces and 30 scratches are present on the back surface of the wafer W. On the other hand, as shown in the lower part of FIG. 7, when the H₂/Ar flow rate ratio at the time of forming the Ti film on the wafer W is set to 5, it was confirmed that 110 dust pieces and 2 scratches are present on the back surface of the wafer W.

From these results, it may be said that dust pieces and scratches generated on the back surface of the wafer W can be greatly reduced by increasing the H₂/Ar flow rate ratio at the time of forming the Ti film on the wafer W from 1.25 to 5.

It should be noted that the embodiment disclosed herein is exemplary in all respects and not restrictive. The above-described embodiment may be omitted, replaced, or modified in various forms without departing from the scope and spirit of the appended claims.

In the above-described embodiment, the film-forming method of forming the Ti film on the wafer W by the plasma CVD method has been described. However, the film-forming method of the present disclosure may also be applied to a case where a film other than the Ti film is formed. Further, the film-forming method of the present disclosure may be applied to a method other than the plasma CVD method, for example, a CVD method not using plasma, and may also be applied to, for example, an atomic layer deposition (ALD) method.

In the above-described embodiment, the semiconductor wafer has been described as an example of the substrate. However, the present disclosure is not limited thereto and may be applied to a substrate other than the semiconductor wafer. Examples of other substrate include a large substrate for a flat panel display (FPD), an EL element and a substrate for a solar cell.

According to the present disclosure in some embodiments, it is possible to reduce defects which may be generated on a back surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film-forming method comprising:
loading a substrate by raising a plurality of lift pins of a mounting table provided in a processing container to receive the substrate and lowering the plurality of lift pins to mount the substrate on an upper surface of the mounting table, the plurality of lift pins being configured to protrude from the upper surface of the mounting table and to support the substrate;
preheating the substrate by heating the substrate mounted on the mounting table in a state in which an inert gas has been introduced into the processing container; and
forming a film on the substrate by introducing a processing gas into the processing container.

2. The method of claim 1, wherein preheating the substrate includes heating the substrate in a state where a gap is provided between the upper surface of the mounting table and a back surface of the substrate.

3. The method of claim 1, wherein preheating the substrate includes gradually increasing a supply amount of the inert gas to a set flow rate at an initial stage of heating.

4. The method of claim 1, wherein the inert gas introduced in preheating the substrate is an Ar gas or an N₂ gas.

5. The method of claim 1, wherein in loading a substrate, the plurality of lift pins are moved at a speed of 1 to 15 mm/sec.

6. The method of claim 1, wherein forming a film includes forming the film on the substrate using plasma of the processing gas.

7. The method of claim 1, wherein the processing gas introduced in forming a film includes a TiCl₄ gas, an H₂ gas and an Ar gas.

8. The method of claim 7, wherein forming a film includes gradually increasing a supply amount of the H₂ gas to a set flow rate and gradually decreasing a supply amount of the Ar gas to a set flow rate at an initial stage of film formation.

9. The method of claim 7, wherein an H₂/Ar flow rate ratio, which is a flow rate ratio of the H₂ gas and the Ar gas introduced in forming a film, is 2 to 10.

10. A film-forming apparatus, comprising:
a processing container;
a mounting table provided in the processing container and having a plurality of lift pins configured to protrude from an upper surface of the mounting table and to support a substrate;
a heating mechanism configured to heat the substrate mounted on the mounting table;
a gas supply part configured to supply a processing gas and an inert gas into the processing container; and
a controller,
wherein the controller is configured to control operations of the mounting table, the heating mechanism and the gas supply part so as to perform:
loading the substrate by raising the plurality of lift pins to receive the substrate and lowering the plurality of lift pins to mount the substrate on the upper surface of the mounting table;
heating the substrate mounted on the mounting table by the heating mechanism in a state where the inert gas has been introduced into the processing container by the gas supply part; and
forming a film on the substrate by introducing the processing gas into the processing container by the gas supply part.
